(19) United States
(12) Patent Application Publication
(10) Pub. No.: US 2008/0002447 A1
(43) Pub. Date: Jan. 3, 2008

(54) Memory supermodule utilizing point to point serial data links

(75) Inventors: Alan Michael Gulachenski, Hopkinton, MA (US); Satyadev Kolli, Milpitas, CA (US); Jan Hendrik Helbers, Marlborough, MA (US)

Correspondence Address: MCDERMOTT WILL & EMERY LLP, 18191 VON KARMAN AVE., SUITE 500, IRVINE, CA, 92612-7108, US

(73) Assignee: SMART Modular Technologies, Inc., Fremont, CA (US)

(21) Appl. No.: 11/478,971

(22) Filed: Jun. 29, 2006

(51) Int. Cl. G11C 5/02

(52) U.S. Cl. 365/51

(57) ABSTRACT

A memory supermodule containing two or more memory modules disposed on a common circuit board. Also, a memory supermodule comprising two or more memory modules, each module comprising a circuit board, the circuit boards connected by a flexible circuit. All modules in a supermodule share a single set of contact pads for establishing signal connection with a system in which the supermodule is used.

### CROSS-REFERENCE(S) TO RELATED APPLICATION(S)

Not Applicable.

### STATEMENT AS TO RIGHTS TO INVENTIONS MADE UNDER FEDERALLY SPONSORED RESEARCH OR DEVELOPMENT

Not Applicable.

### BACKGROUND OF THE INVENTION

The present invention generally relates to integrated circuit assemblies, and in particular, to memory modules.

Since the advent of electronic computers, computer makers have desired to put more computing power into smaller spaces. For example, computer makers want to minimize the amount of printed circuit board area they use. Alternatively, computer makers want to fit more circuitry into the prescribed dimensions of industry standard system boards.

For use in computers, semiconductor memory is normally supplied in the form of pluggable modules. For a given amount of memory, computer makers want to minimize the board space used by the modules and their associated sockets. In some applications, however, module height is also a constraint. Thus it would be desirable to fit more memory on a single module.

Recently, a new memory architecture has entered the marketplace, offering many advantages. The Fully Buffered Dual Inline Memory Module. (FB-DIMM) was developed to overcome the issue of higher memory bus speeds limiting the number of DIMMs that could be used. The FB-DIMMs enable bus speed to be increased while being able to maintain the amount of memory used per channel. Advanced Memory Buffer (AMB) circuits on each DIMM use a high speed differential point-to-point multi-lane serial link to pass commands and data from a memory controller to the DIMMs, and pass data from the DIMMs to the memory controller.

FIG. 1a and FIG. 1b show the component layout of a FB-DIMM 100. FIG. 1a shows the top side; FIG. 1b shows the bottom side. The FB-DIMM 100 includes the Advanced Memory Buffer device 110, a plurality of Dynamic Random Access Memory devices (DRAMs) 120, and a circuit board 140. The circuit board 140 has a set of contact pads 150. The AMB 110 receives data from the DRAMs 120 and sends data and commands to the DRAMs 120. The DRAMs 120 store the received data. The circuit board 140 provides mechanical support to the other devices, as well as electrical connection between the devices and the contact pads 150. The contact pads 150 provide electrical connection between the DIMM 100 and a mating socket, such as an edge connector, installed in a system, such as a computer.

FIG. 2 shows how FB-DIMMs function in a system. A system memory controller 260 sends write data and commands through a FBD Channel Interface to the AMB 210 on the FB-DIMM 200 in Socket 1 via the set of contact pads 250. All of the actual sockets are omitted from the drawing for clarity. In turn, the AMB 210 sends the commands and write data to the DRAMs 220. The AMB 210 on DIMM 200 also forwards commands and write data to the next FB-DIMM 221 in Socket 2. Similarly, the AMB 210 on DIMM 200 receives read data from the DRAMs 220, or from FB-DIMMs in sockets further away from the memory controller 260, and forwards the data to the memory controller 260. The AMB 210 also supports an SMBus interface. For completeness, a clock circuit, 270 supplies clock signal to all of the other components.

It would be desirable if the features offered by the FB-DIMM architecture could be used to fit more memory on a single memory module, so that board space can be minimized for a given amount of memory.

### SUMMARY OF THE INVENTION

In one embodiment, a memory supermodule is disclosed. The memory supermodule includes two or more sets of integrated circuits disposed on a single circuit board. Each set of integrated circuits includes a buffer device and a plurality of memory devices coupled to the buffer device. Each set of integrated circuits generally corresponds to a set on a single memory module.

In another embodiment, a memory supermodule is disclosed. The memory module includes a circuit board having a first surface, a second surface, and a single set of contact pads. The set of contact pads is configured to connect to a circuit external to the supermodule. The memory module also includes a first set and a second set of integrated circuits. Each set of integrated circuits is disposed on the circuit board. The first set includes a first buffer device and multiple memory devices. These multiple memory devices are coupled to the first buffer device. The second set of integrated circuits includes a second buffer device and multiple memory devices. These multiple memory devices are coupled to the second buffer device. Within each set, the buffer device is configured to send write data to the memory devices and receive read data from the memory devices. Each buffer device is configured also to send information to, and receive information, from the other buffer device. Both sets of integrated circuits share the set of contact pads for communicating with the external circuit.

In another embodiment, a memory supermodule is disposed. The memory supermodule includes two or more circuit boards. The circuit boards are connected to each other by flexible circuits. A set of integrated circuits is disposed on each circuit board. Each set of integrated circuits includes a buffer device and multiple memory devices. Within each set, the multiple memory devices are coupled to the buffer device. Within each set, the buffer device is configured to send write data to the memory devices and receive read data from the memory devices. Each buffer device is configured also to send information to, and receive information from, the other buffer device.

In another embodiment, a computer system is disclosed. The computer system includes a memory supermodule.

The present invention may offer a number of benefits and/or advantages. Combining multiple DIMMs on one circuit board means fewer sockets need to be provided by the system. Fewer sockets means that less board space need be taken up by sockets. Packaging technology that allows stacking of DRAMs will lower the overall height of the memory module.

Reference to the remaining portions of the specification, including the drawings and claims, will realize other features and advantages of the present invention. Further features and advantages of the present invention, as well as the structure and operation of various embodiments of the present invention, are described in detail below with respect to accompanying drawings, like reference numbers indicate identical or functionally similar elements.

### BRIEF DESCRIPTION OF THE DRAWINGS

Aspects, advantages and novel features of the present invention will become apparent from the following description of the invention presented in conjunction with the accompanying drawings:

FIG. 1a is a component mounting diagram of the top side of a standard FB-DIMM memory module;

FIG. 1b is a component mounting diagram of the bottom side of a standard FB-DIMM memory module;

FIG. 2 is a simplified schematic representation of standard FB-DIMMs used in a system, interconnected to the system's memory controller and the system's clock;

FIG. 3a is a component mounting diagram of the front side of one embodiment of the invention;

FIG. 3b is a component mounting diagram of the bottom side of one embodiment of the invention;

FIG. 4a is a component mounting diagram of another embodiment of the invention;

FIG. 4b is a component mounting diagram of another embodiment of the invention;

FIG. 5 is a component mounting diagram of another embodiment of the invention;

FIG. 6 is a simplified schematic representation of the prior art, showing how an AMB circuit on a DIMM interfaces with upstream DIMMs, if any, and with either the memory controller or with downstream DIMMs; and

FIG. 7 shows a simplified schematic representation of one embodiment of the invention, showing how two AMB circuits interface with each other, as well as with other DIMMs and the memory controller.

FIG. 8 shows a simplified schematic representation of another embodiment of the invention, with more than two AMB circuits.

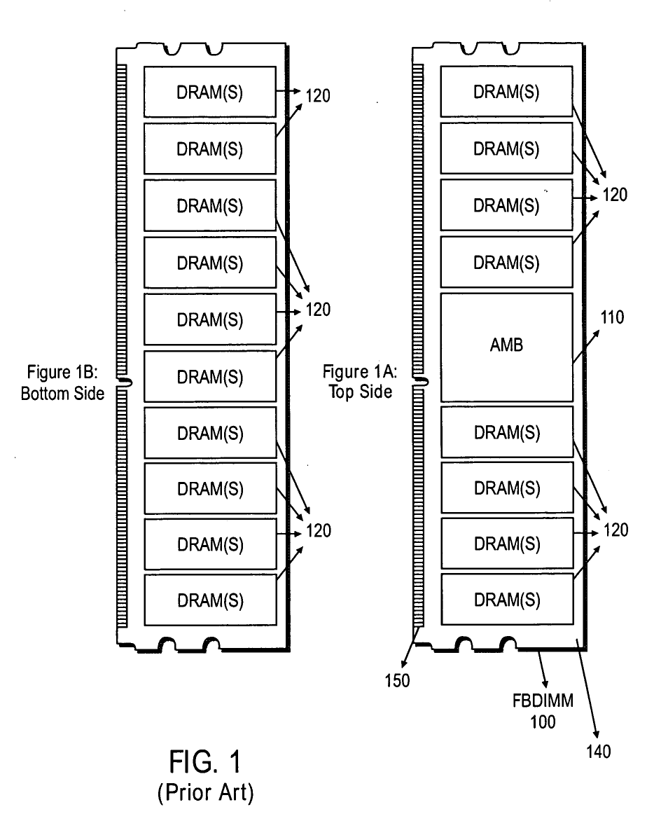

### DETAILED DESCRIPTION OF ILLUSTRATIVE EMBODIMENTS

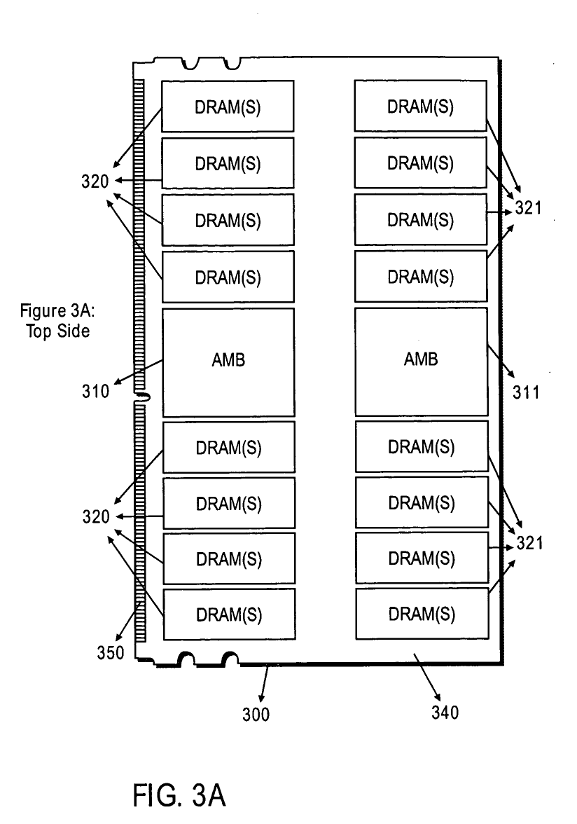

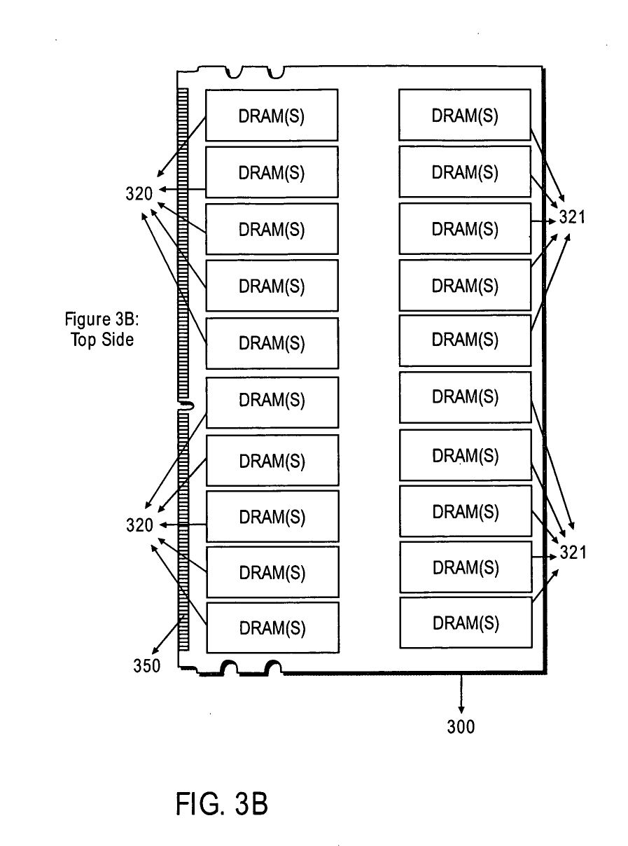

One or more embodiments of the present invention will now be described. FIG. 3a and FIG. 3b show a component mounting layout of an exemplary memory supermodule 300, including two Advanced Memory Buffer buffer devices 310 and 311, two sets of 18 DRAM memory devices 320 and 321, and a circuit board 340 carrying one single set of contact pads 350. The single set of contact pads is disposed in two rows: one on the top side of the supermodule, and one on the bottom side. FIG. 3a shows the top side of the supermodule; FIG. 3b shows the bottom side. Both AMBs 310 and AMB 311 are mounted to the same side of the circuit board 340. AMB 310 receives data from the DRAMs 320, and sends data and commands to the DRAMs 320. Similarly AMB 311 receives data from and sends commands and data to the DRAMs 321. AMB 310 and AMB 311 also communicate with each other, passing data and/or commands between themselves. The DRAMs 320 store the data received from and sent to their associated AMB. The circuit board 340 provides mechanical support to the other devices, as well as providing electrical connection between the devices as well as from the devices to the contact pads 350. The contact pads 350 are bare and/or plated metal pads. The contact pads are electrically connected to the Advanced Memory Buffer devices 310 and 311. The contact pads 350 provide electrical connection between the DIMM 300 and a mating system socket (not shown).

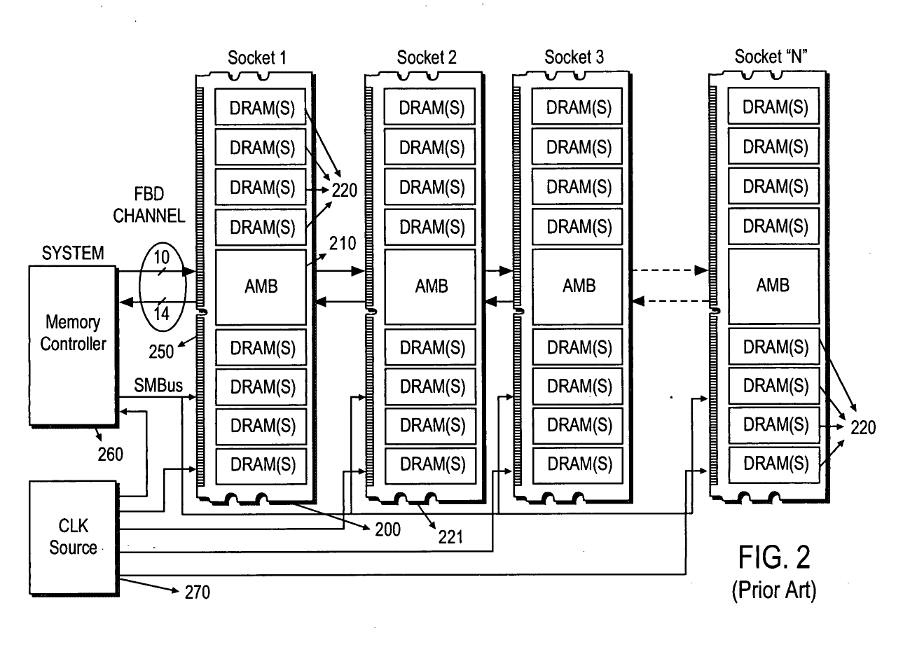

Once installed in a system, such as the system of FIG. 2, the AMB 310 receives commands and write data from the system memory controller (not shown) by means of the FBD Channel Interface (not shown) via the set of contact pads 350. The AMB 310 sends the commands and write data to the DRAMs 320. The AMB 310 forwards command and write data to an AMB on the same circuit board, AMB 311, instead of to an AMB on the next furthest away FB-DIMM, as in the case of the standard FB-DIMM. It is AMB 311 that forwards command and write data to an AMB on the next furthest away FB-DIMM. Similarly, the AMB 311 receives read data from the FB-DIMMs further away from the memory controller, and forwards the data to AMB 310 to send towards the memory controller. Both AMB 310 and AMB 311 receive read data from and send write data to their respective sets of DRAM 320 and 321.

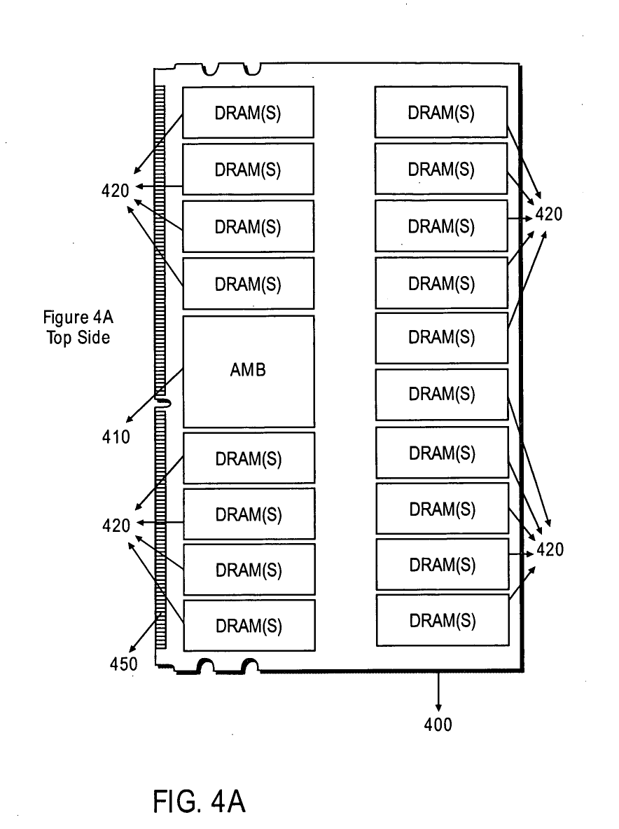

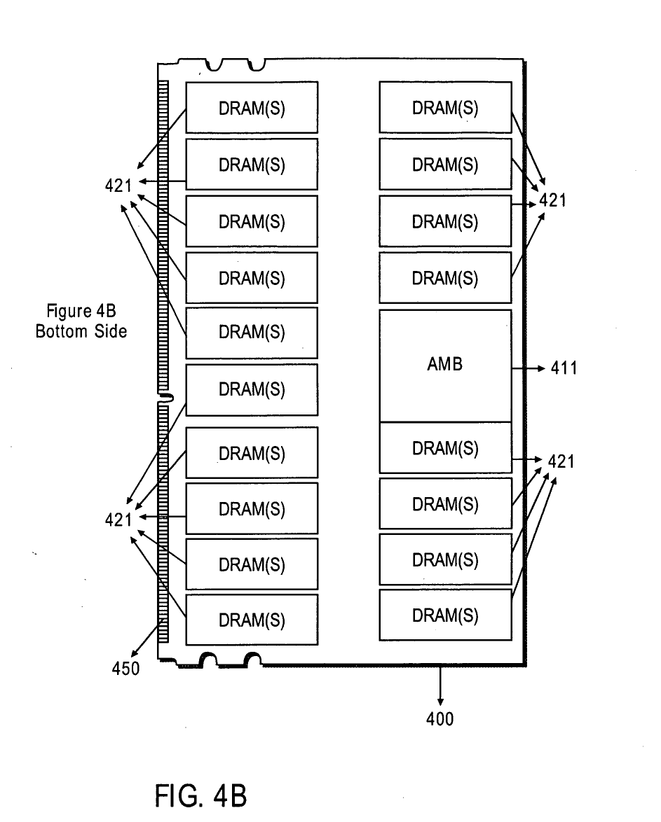

FIG. 4 is another embodiment of the invention, similar to the embodiment depicted in FIG. 3a and FIG. 3b, except that one AMB device is mounted to each side of the circuit board. In other words, AMB 410 is mounted to one side of circuit board 440, and AMB 411 is mounted to the other side.

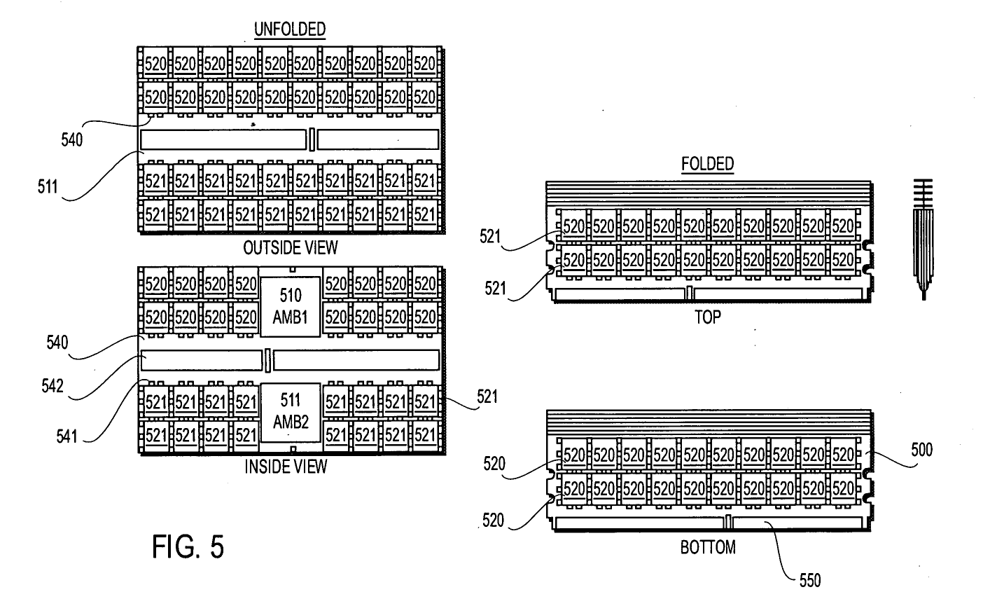

FIG. 5 shows another embodiment of the invention, similar to the previous ones except that the circuit board between each set of buffer and memory devices is sufficiently flexible to be folded. One buffer device 510 and one set of memory devices 520 are mounted to circuit board 540, while buffer device 511, and another set of memory devices 521 are mounted to another circuit board 541, the two circuit boards being joined by a foldable circuit 542. The foldable circuit 542 carries a set of contact pads 550. The circuit boards and mounted devices are symmetrical about the centerline of foldable circuit 542. After the devices are mounted to the circuit board, the supermodule 500 is folded along the centerline of foldable circuit 542, so that the top surfaces of similar devices in the “Inside View,” for example buffer devices 510 and 511, touch each other. The folded supermodule can be secured by gluing the top surfaces of similar devices together. After folding is completed, the set of contact pads 550 can be inserted into a socket the same as other embodiments of the invention.

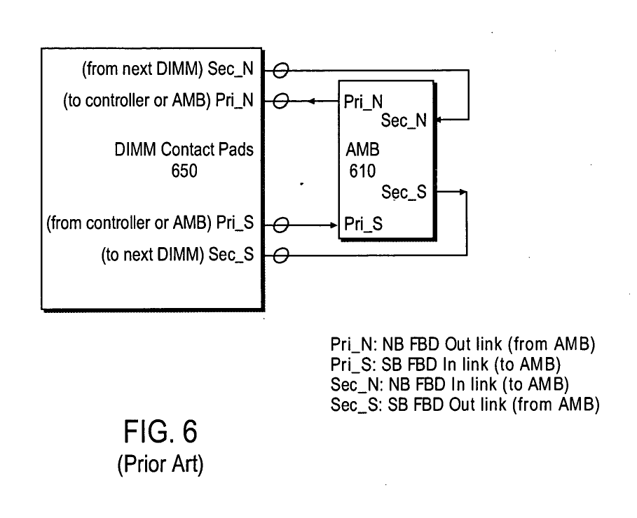

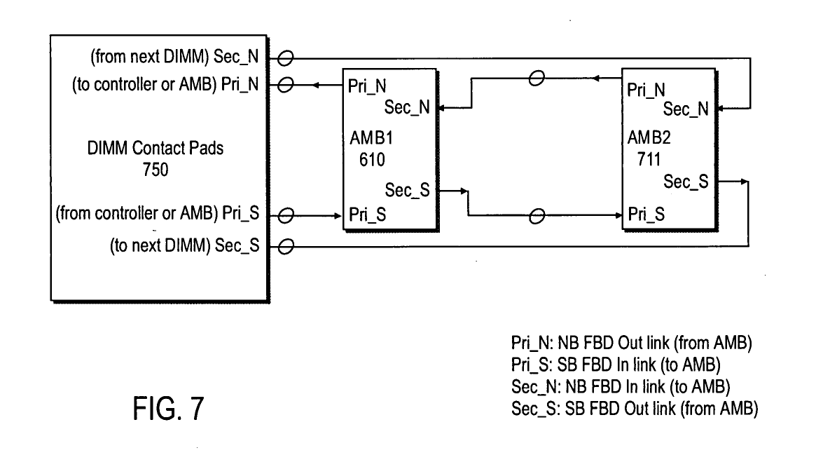

The difference between prior art and these embodiments can also be seen by reference to FIG. 6 and FIG. 7. The FBD Channel Interface is divided into a northbound (NB) link and a southbound (SB) link. FIG. 6 depicts the prior art. Here, commands and write data come from the memory controller through the primary southbound in link, Pri_S to the AMB 610, via the DIMM contact pads 650. The AMB 610 forwards the command and write data to the DIMM that is the next furthest from the memory controller through the secondary southbound out link, Sec_S, via the DIMM contact pads 650. The AMB 610 receives read data and status information from DIMMs further from the memory controller through the secondary northbound in link, Sec_N, via the DIMM contact pads 650. The AMB 610 forwards the read data and status information either to the DIMM next closest to the memory controller, or to the memory controller itself, through the primary northbound out link, Pri_N, via the DIMM contact pads 650.

FIG. 7 depicts an embodiment of the invention. There are two main differences between this embodiment of the invention and the prior art: The AMB 710 forwards the command and write data to another AMB 711 on the same circuit board, through the secondary southbound out link Sec_S, not to another DIMM. Similarly, AMB 710 receives read data and status information from AMB 711 on the same circuit board through the secondary northbound in link, Sec_N, not from another DIMM.

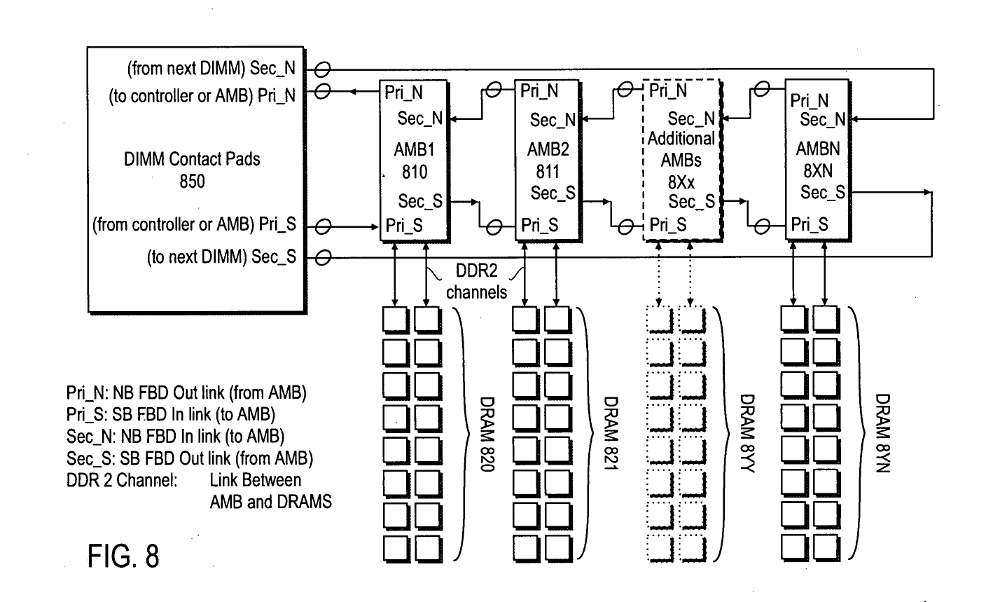

In another embodiment of the invention, more than two sets of AMB and associated DRAMs are disposed on a single circuit board. For example, there can be 10 sets of AMB and associated DRAMs disposed on a single circuit board. FIG. 8 is a simplified schematic representation of this embodiment, showing how AMB 810 forwards the command and write data to another AMB 811 on the same circuit board, then from 811 through a series of AMBs until AMB 8XN is reached, through the secondary southbound out link Sec_S. Similarly, AMB 810 receives read data and status information from AMB 811, which received the data and status information from the same series of AMBs on the same circuit board, starting with the furthest away AMB, AMB 8XN, through the secondary northbound in link, Sec_N. If there are 10 sets of AMB and associated DRAMs disposed on a single circuit board, XN will be 30: X=3, and N=0. Also shown is the set of DRAMs 820 associated with AMB 810. AMB 810 reads data from and writes data to the DRAMs 820 via DDR2 channels.

In another embodiment of the invention, a computer system including a memory supermodule is disclosed. The computer system includes a system memory controller and a clock (CLK) source as in FIG. 2. In an exemplary embodiment, the computer system includes the memory supermodule of FIG. 3. In another embodiment, the computer system includes the memory supermodule of FIG. 4. In still another embodiment, the computer system includes the memory supermodule of FIG. 5.

Combining two or more memory modules into a single supermodule minimizes the amount of system board space used by modules and their associated sockets. For example, for supermodules containing two memory modules each, only half the number of sockets is required for the same amount of memory. The folding module shown in FIG. 5 minimizes the height of the supermodule, for system applications in which module height is also a constraint.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention not be limited by this detailed description, but by the claims and the equivalents to the claims appended hereto.

What is claimed is:

1. A memory supermodule comprising:
a circuit board; and
two or more sets of integrated circuits disposed on the circuit board, each set comprising a buffer device and a plurality of memory devices coupled to the buffer device.

2. A memory supermodule comprising:
a circuit board having a first surface, a second surface, and a single set of contact pads, the set of contact pads configured to connect to a circuit external to the supermodule; and
a first set and a second set of integrated circuits disposed on the circuit board,
wherein:
the first set of integrated circuits comprises a first buffer device and a plurality of memory devices coupled to the first buffer device;
the second set of integrated circuits comprising a second buffer device and a plurality of memory devices coupled to the second buffer device; and
each buffer device configured to send write data to the memory devices and receive read data from the memory devices;
wherein the two sets of integrated circuits share the set of contact pads for communicating with the external circuit.

3. The memory supermodule of claim 2, wherein both buffer devices are mounted to the first surface of the circuit board.

4. The memory supermodule of claim 2, wherein:
the first buffer device is mounted to the first surface of the circuit board, and
the second buffer device is mounted to the second surface of the circuit board.

5. The memory supermodule of claim 2, wherein:
the first buffer device:
receives commands and write data via the contact pads; and
forwards the commands and write data to the second buffer device; and
the second buffer device:
receives read data and status information via the contact pads; and
forwards the read data and status information to the first buffer device.

6. A memory supermodule comprising:
two or more circuit boards; and
a set of integrated circuits disposed on each circuit board, each set comprising a buffer device and a plurality of memory devices coupled to the buffer device;
wherein the circuit boards connected by flexible circuits.

7. The memory supermodule of claim 6 further comprising:
a set of electrical contact pads mounted to the flexible circuit, the set of contact pads configured to connect to a circuit external to the supermodule; and
each set of integrated circuits being electrically connected to the set of electrical contact pads.

8. A computer system comprising the memory supermodule of claim 1.

9. A computer system comprising the memory supermodule of claim 6.
